(19) United States
(12) Patent Application Publication
(10) Pub. No.: US 2010/0193034 A1
(43) Pub. Date: Aug. 5, 2010

(54) ORGANIC-INORGANIC HYBRID JUNCTION DEVICE USING REDOX REACTION AND ORGANIC PHOTOVOLTAIC CELL OF USING THE SAME

(75) Inventors: Kwang-Hee Lee, Gwangju-City (KR); Sung-Heum Park, Gwangju-City (KR); Hee-Joo Kim, Gwangju-City (KR)

Correspondence Address: OSHA LIANG L.L.P., TWO HOUSTON CENTER, 909 FANNIN, SUITE 3500, HOUSTON, TX, 77010, US

(73) Assignee: Gwangju Institute of Science and Technology, Gwangju-City (KR)

(21) Appl. No.: 12/678,372

(22) PCT Filed: Sep. 18, 2008
(86) PCT No.: PCT/KR2008/005525

§ 371 Date: Mar. 16, 2010

(30) Foreign Application Priority Data
Sep. 18, 2007 (KR) 10-2007-0094992

(51) Int. Cl. H01L 51/46; H01L 51/30

(52) U.S. Cl. 136/263; 257/40; 257/E51.027

(57) ABSTRACT

Provided are an organic-inorganic hybrid junction device in which organic and inorganic materials are connected by junction, and a depletion layer is formed at a junction interface, and an organic photovoltaic cell using the same. A basic metal oxide solution is applied to a top surface of a P-doped organic layer. The basic metal oxide solution has N-type characteristics. An oxidation-reduction reaction occurs in response to the application of the basic metal oxide solution at a junction interface of the organic layer, and the metal oxide layer is simultaneously gelated. A free charge is removed from a surface region of the P-doped organic layer by the oxidation-reduction reaction at the interface, which is converted into a depletion region. According to the introduction of the depletion region, P-N junction occurs, and thus the device has a diode characteristic in an electrical aspect. Also, an organic photovoltaic cell including the organic layer, the depletion layer and the metal oxide layer is fabricated.

### TECHNICAL FIELD

The present invention relates to a junction device using an organic-inorganic hybrid depletion layer, and a photovoltaic cell using the same.

### BACKGROUND ART

Semiconductor device technology based on P-N junction is considered a driving power for increasing the quality of human life and dramatically developing the world economy in the post-industrial revolution era. Such semiconductor device technology has been widely applied in various fields of society, for example, displays, imaging systems, communication equipment, digital appliances, mobile phones, digital cameras, camcorders, and MP3 players, and has played a critical role in the advent of today's information and knowledge-based society. Meanwhile, as the development to the super-high speed information society further accelerates at the beginning of this 21st century, it is expected that society will enter an era in which information and technology are so ubiquitous that we can easily search for desired information anytime and in anyplace through a digital network. Accordingly, for future information devices, high-performance in marked qualities, and downsizing and multifunction of the devices will be emphasized, and flexible, portable and wearable electronic devices will be in the mainstream.

Thus, multifunctional and novel electronic devices responding to the upcoming ubiquitous era need to develop, and therefore, dramatic development of the semi-conductor technology, which was the driving power leading to the development of science and technology in 20th century, is the first consideration. However, unlike the need of the times, the current semiconductor devices using inorganic P-N junctions are large, heavy and formed in complicated fabrication processes. In addition, the current devices are vulnerable to external impact, and thus there is a limit in their use as the next generation electronic devices which have to be formed in a super thin film and super fine structure.

For these reasons, intensified development of electronic devices using an organic material as an active layer are being made today, which are considered the closet technology to implementing next generation super thin and super fine electronic devices since organic semiconductors have better cost-down effect, lighter weight, are easily handled and fabricated, and particularly, are able to withstand external impact due to durability.

However, since such electronic devices using organic materials are also vulnerable to oxygen and moisture, they have a shorter life span and lower performance than inorganic electronic devices. In addition, in order to fabricate super thin devices and nano-scaled electronic devices required for the future, new technology is needed. Thus, new semiconductor technology capable of overcoming the disadvantages of the organic and inorganic materials and at the same time preserving the advantages of these materials is needed.

### DISCLOSURE OF INVENTION

### Technical Problem

The present invention is directed to a junction device having an organic-inorganic hybrid junction characteristic.

The present invention is also directed to an organic photovoltaic cell using the junction device provided by accomplishing the above object.

### Technical Solution

One aspect of the present invention provides an organic-inorganic hybrid junction device, including: an organic layer doped with a P-type dopant; a metal oxide layer doped with an N-type dopant, and formed by gelation of a basic metal oxide solution; and a depletion layer interposed between the organic layer and the metal oxide layer, and formed by dedoping the organic layer at an interface between the organic layer and the metal oxide layer in response to an oxidation-reduction (redox) reaction of the organic layer and the metal oxide solution.

Another aspect of the present invention provides an organic photovoltaic cell, including: a first electrode formed on a substrate; an organic layer doped with a P-type dopant formed on the first electrode; a metal oxide layer doped with an N-type dopant and formed by gelation of a basic metal oxide solution; a depletion layer interposed between the organic layer and the metal oxide layer, formed by dedoping of the organic layer at an interface between the organic layer and the metal oxide layer in response to a redox reaction of the organic layer and the metal oxide solution, and producing a free charge by light absorption; and a second electrode formed on the metal oxide layer.

Still another aspect of the present invention provides an organic photovoltaic cell, including: an organic layer formed on a substrate and doped with a P-type dopant; a depletion layer, formed along the uneven organic layer, and producing a free charge by light absorption; and a metal oxide layer formed on the depletion layer. Here, the depletion layer is formed by dedoping of the organic layer at an interface between the organic layer and the metal oxide layer in response to a redox reaction of the organic layer and the metal oxide solution, and the metal oxide layer is formed by gelation of the metal oxide solution.

### Advantageous Effects

According to the present invention, a depletion layer is formed between two different kinds of materials such as a P-doped organic layer and an N-doped metal oxide solution by junction. That is, an oxidation-reduction (redox) reaction occurs due to a basic metal oxide solution, and a P-doped organic layer is changed into a depletion layer in which a free charge is removed. At the same time, the metal oxide solution is gelated, thereby being changed into a metal oxide layer. Due to the application of the metal oxide layer, a photovoltaic cell may be easily encapsulated. Thus, protection from moisture or air can be easily performed. Also, the depletion layer is formed on a surface of the P-doped organic layer, and thus may have a relatively very small thickness. Using such a thin depletion layer as a photoactive layer in the organic photovoltaic cell, a migration distance of a free charge generated by absorption of light can be reduced as much as possible. Thus, the efficiency of the organic photovoltaic cell can be maximized.

In addition, a separate process for forming a photoactive layer is not required, and a photoactive layer, which is a depletion layer, and an electron-acceptor layer, which is a metal oxide layer, can be formed in one process.

### BRIEF DESCRIPTION OF THE DRAWINGS

FIG. 1 is a cross-sectional view showing a method of forming an organic-inorganic hybrid depletion layer according to a first example embodiment of the present invention.

FIG. 2 is a cross-sectional view of a photovoltaic cell according to the first example embodiment of the present invention.

FIG. 3 is a graph of transmittance spectra for four kinds of thin films formed according to Example 1.

FIG. 4 is a graph of transmittance spectra for films formed according to Example 2.

FIG. 5 is a graph of voltage-current characteristics of a device structure sequentially including a glass substrate, an aluminum electrode, a titanium oxide A layer, an organic layer and an aluminum electrode according to Example 3.

FIG. 6 is a graph of voltage-current characteristics of a device structure sequentially including a glass substrate, an aluminum electrode, an organic layer, a titanium oxide A layer and an aluminum electrode according to Example 3.

FIG. 7 is a graph of voltage-current characteristics of an organic photovoltaic cell fabricated according to Example 4.

FIG. 8 is a cross-sectional view of an organic photovoltaic cell according to a second example embodiment of the present invention.

### MODE FOR THE INVENTION

Hereinafter, the present invention may be modified in various forms, and thus example embodiments will be illustrated in drawings and described in detail. The present invention is not limited to the example embodiments disclosed below, but on the contrary, the present invention is to cover modifications, equivalents and alternatives falling within the spirit and scope of the present invention. In the drawings, like reference numerals denote like elements.

Unless otherwise defined, all terms used herein including technical or scientific terms have the same meanings as those which are generally understood by one of ordinary skill in the art. It should be clear that terms defined by dictionaries are generally used to have meanings corresponding to those from the context in related technology, and if not clearly defined herein, are not to be understood with ideal or excessively formal meanings.

Hereinafter, example embodiments of the present invention will be described in more detail with reference to the accompanying drawings.

### Example Embodiment 1

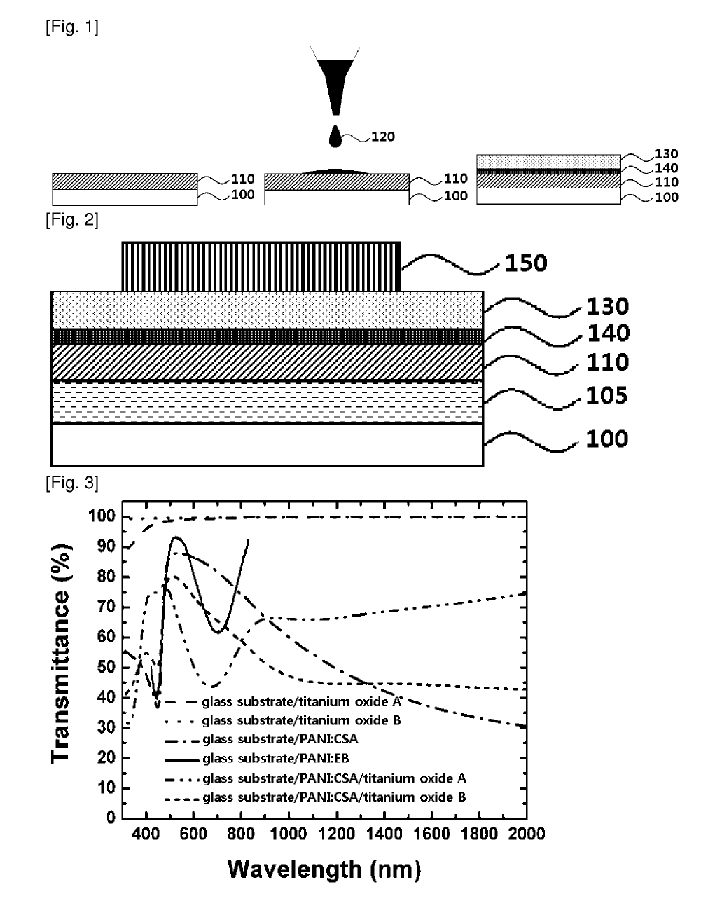

FIG. 1 is a cross-sectional view for explaining a method of forming an organic-inorganic hybrid depletion layer according to a first example embodiment of the present invention. In FIG. 1, an organic-inorganic hybrid junction device is formed.

Referring to FIG. 1, an organic-inorganic hybrid junction device includes an organic layer 110 formed on a substrate 100, a depletion layer 140 formed on the organic layer 110 and a metal oxide layer 130 formed on the depletion layer 140.

First, the organic layer 110 is formed on the substrate 100.

The substrate 100 may be any one capable of accommodating the organic layer 110, and thus may be formed of glass, paper or plastic such as polyethylene terephthalate (PET), polyethersulfone (PES), polycarbonate (PC), polyimide (PI), polyethylene naphthalate (PEN) or polyarylate (PAR).

The organic layer 110 on the substrate 100 may be used after doping a polymer selected from the group consisting of polyaniline-, polypyrrol-, polyacethylene-, poly(3,4-ethylenedioxythiophene) (PEDOT)-, poly(phenylenevinylene) (PPV)-, poly(fluorene)-, poly(para-phenylene) (PPP)-, poly(alkyl-thiophene)-, and poly(pyridine) (PPy)-doped materials and combinations thereof. The organic layer 110 formed on the substrate 100 is doped with a P-type dopant. All kinds of the coating methods known conventionally may be applied to the organic layer 110 so it may be formed in various methods.

Subsequently, a base layer is formed on the organic layer 110. The base layer is a metal oxide layer 130, and has N-type characteristics. Preferably, the base layer is formed by coating a basic metal oxide solution 120.

The metal oxide solution 120 is prepared by the following process. First, under conditions in which oxygen and moisture are removed, metal alkoxide is mixed with a solvent and an additive to form a metal oxide intermediate solution. Subsequently, the metal oxide intermediate solution is condensed by applying heat, and thus a gel-type metal oxide is formed. Then, a dispersion solution is added to the gel-type metal oxide, thereby forming a metal oxide solution.

During the preparation process of the metal oxide solution, the metal alkoxide may include Ti, Zn, Sr, In, Ba, K, Nb, Fe, Ta, W, Sa, Bi, Ni, Cu, Mo, Ce, Pt, Ag, Rh, Ru or a combination thereof as a metal. Also, the solvent used in the process is alcohol, such as ethanol, methanol or isopropanol, and the additive used herein is alcohol amine such as ethanol amine, methanol amine or propanol amine, hydrogen peroxide, or ammonium hydroxide.

Preferably, the metal alkoxide is titanium alkoxide. Thus, the metal oxide solution may be a titanium oxide solution.

The metal oxide intermediate solution, i.e., the titanium oxide intermediate solution, consists of 5 to 60% metal alkoxide and a 5 to 20% additive by volume of a solvent.

Subsequently, the titanium oxide intermediate solution is concentrated. In the concentration process, the solvent is removed by applying heat to the titanium oxide intermediate solution, which leads to facilitate the additive to bind to the titanium alkoxide. The heat applied for the concentration process ranges from 60 to 180° C. The titanium oxide intermediate solution is transformed in a gel type through the concentration, and becomes a titanium alkoxide mixture. That is, during the concentration process, the metal alkoxide binds to the additive, thereby forming a gel-type metal oxide.

Then, a dispersion solution is added to the gel-type titanium oxide. The dispersion solution can be alcohol such isopropanol, ethanol or methanol, chloroform, chlorobenzene, dichlorobenzene, THF, xylene, DMF, DMSO, or toluene. The dispersion solution is mixed with the gel-type titanium alkoxide mixture, thereby obtaining the metal oxide solution 120 to be obtained in the present invention, which is a titanium oxide solution. The dispersion may have a volume percentage of 1000 to 20000% based on the contained metal alkoxide.

The titanium oxide solution formed through the above-described processes is applied to a top of the organic layer 110 formed on the substrate 100.

The metal oxide solution 120 may be applied by a spin-coating, dip-coating, ink-jet printing, screen printing, doctor-blade, drop casting, stamp, or roll-to-roll printing method.

When the liquid-type metal oxide solution 120 is applied, it is exposed to the air or moisture, and gelated by hydrolysis with the air or moisture. Also, the metal oxide solution 120 has basic character. The metal oxide layer 130 is formed on the organic layer 110 by the gelation of the basic metal oxide solution 120, which simultaneously reacts with the organic layer 110 in response to an oxidation-reduction (redox) reaction. That is, the redox reaction occurs at an interface between the organic layer 110 and the metal oxide solution 120.

A dedoping phenomenon occurs at the interface in response to the redox reaction. That is, a hole, i.e., a charge carrier, is removed from a part of the P-doped organic layer 110. That is, a depletion layer 140 is formed by dedoping the organic layer 110 between the metal oxide layer 130 formed by gelation and the organic layer 110. That is, since an electron is combined with a hole at an interface where a P-doped layer is in contact with an N-doped layer, a part of the organic layer 110 is changed into an electrically-neutral region which does not exhibit electrical conductivity. Thus, an electrically-neutral depletion layer 140 is formed between the P-doped organic layer 110 and the N-doped metal oxide layer 130.

The depletion layer 140 is formed by dedoping the P-doped organic layer 110, whose thickness and dedoping degree are dependant on the pH of the metal oxide solution 120. Accordingly, in FIG. 1, the depletion layer 140 is formed on the organic layer 110, and the titanium oxide layer is formed on top of the depletion layer 140.

FIG. 2 is a cross-sectional view of an organic photovoltaic cell according to the first example embodiment of the present invention.

Referring to FIG. 2, a first electrode 105 is formed on a substrate 100.

The substrate 100 may be formed of glass, paper, plastic such as PET, PES, PC, PI, PEN or PAR, or a combination thereof. The first electrode 105 may be formed of one selected from the group consisting of indium tin oxide (ITO), Al-doped zinc oxide (AZO), indium zinc oxide (IZO), and combinations thereof.

Subsequently, an organic layer 110 is formed on the first electrode 105.

The organic layer 110 may include a polyaniline-, polypyrrol-, polyacethylene-, poly(3,4-ethylenedioxythiophene) (PEDOT)-, poly(phenylenevinylene) (PPV)-, poly(fluorene)-, poly(para-phenylene) (PPP)-, poly(alkyl-thiophene)-, or poly(pyridine) (PPy)-based material.

A metal oxide solution 120 exhibiting basic character in a liquid state is coated on the organic layer 110. The metal oxide solution may be coated by a spin-coating, dip coating, ink-jet printing, screen printing, doctor-blade, drop casting, stamp, or roll-to-roll printing method.

The metal oxide solution 120 is exposed to the air or moisture, and gelated via hydrolysis with the air or moisture. In addition, the metal oxide layer 130 is formed on the organic layer 110 by gelation of the metal oxide solution 120 exhibiting basicity, which simultaneously reacts with the organic layer 110 in response to a redox reaction. That is, the redox reaction occurs at an interface between the organic layer 110 and the metal oxide solution.

A dedoping phenomenon occurs at the interface in response to the redox reaction. That is, a hole, i.e., a charge carrier, is removed from a part of the P-doped organic layer 110. That is, a depletion layer 140 formed by dedoping the organic layer 110 is formed between the metal oxide layer 130 formed by gelation and the organic layer 110. This is because an electron is combined with a hole at an interface where a P-doped layer is in contact with an N-doped layer, and thus the organic layer is changed into an electrically-neutral region which does not exhibit electrical conductivity.

That is, the depletion layer 140 is formed by dedoping the P-doped organic layer 110, whose thickness and dedoping degree are dependant on the pH of the metal oxide solution.

A second electrode 150 is formed on the metal oxide layer 130.

The second electrode 150 is formed of one selected from the group consisting of Al, Ba, Ca, In, Cu, Ag, Au, Yb, Sm and combinations thereof.

When the depletion layer 140 absorbs light, a charge generated from the depletion layer 140 easily migrates to the second electrode 150 through the metal oxide layer 130.

That is, since a thickness of the depletion layer 140 is very small due to the redox reaction, a distance at which the electron and the hole generated in the depletion layer 140 can easily migrate is short. Currently, one of the reasons for reduced efficiency of the organic photovoltaic cell is long-distance migration of the electron and the hole to an electrode, while the mobility of the electron and hole is low in a photoactive layer where a charge is generated. It is substantially impossible to control a thickness of a photoactive layer formed by a conventional doping process, and thus difficult to form a photoactive layer that is several tens of nanometers thick. In the present invention, the depletion layer formed using the redox reaction at the interface is used as the photoactive layer. Thus, the depletion layer having no pin-hole formed to a thickness of several to several tens of nanometers is used as the photoactive layer, and the migration distance of the electron and hole generated by light absorption may be minimized. As a result, the efficiency of the photovoltaic cell can be maximized.

### Example 1

### Formation of Depletion Layer Using Polyaniline and Titanium Oxide Solution and Analysis of Its Characteristics

In Example 1, polyaniline was applied to an organic layer shown in FIGS. 1 and 2. Also, the polyaniline was p-doped with camphorsulfonic acid (CSA). A titanium oxide solution was used as a metal oxide solution formed on the organic layer. Basic titanium oxide A with a pH of 11 and acidic titanium oxide B with a pH of 3 were coated, and occurrence of a redox reaction was confirmed to compare depletion layers formed using them to each other.

First, the titanium oxide solution was made into a titanium oxide intermediate solution by mixing titanium alkoxide, titanium (IV) isopropoxide, with a solvent, 2-methoxyethanol, and an additive, ethanolamine, and stirring the resulting mixture under conditions in which oxygen and external air were blocked. The titanium oxide intermediate solution was condensed to obtain a gel-type titanium oxide. Finally, a dispersion solution was added to obtain a titanium oxide solution. The above-mentioned pH of the titanium oxide solution may be easily obtained by selection and control of the mixed additive or solvent.

Subsequently, the polyaniline doped with the camphorsulfonic acid was dissolved in meta-cresol, and the resulting solution was dropped on a glass substrate, which was rotated at 3000 rpm for 3 minutes and annealed on a hot plate at 90° C. for 2 hours to form an organic layer. In addition, the titanium oxide A (pH 11) and the titanium oxide B (pH 3) prepared by the above-described method were dropped on respective glass substrates, which were rotated at 300 rpm for 1 minute and annealed on a hot plate at 90° C. for 2 hours to form thin films. Afterward, optical transmittance spectra of the formed thin films were measured by a UV-Vis spectrometer.

In addition, the formed organic layer containing polyaniline was coated with the basic titanium oxide A solution and the acidic titanium oxide B solution to form depletion layers via the redox reaction. Optical characteristics with respect to membranes formed through the above-described process were analyzed by a UV-Vis spectrometer.

FIG. 3 is a graph of transmittance spectra for four kinds of thin films formed according to Example 1. In FIG. 3, PANI:CSA refers to polyaniline doped with camphorsulfonic acid, and PANI:EB refers to polyaniline-emeraldine base.

Referring to FIG. 3, an organic layer consisting of polyaniline doped with camphorsulfonic acid exhibits typical characteristics of conductive polymer. That is, a Drude peak exhibiting a metallic characteristic was observed in a range from 600 to 2000 nm. On the other hand, it is shown that almost no absorption of titanium oxides A and B was observed in a range from 300 to 2000 nm, which is a range for measuring transmittance, and high transmittance was observed in a range of a visible ray.

Meanwhile, the titanium oxide A formed on the organic layer consisting of a polyaniline film doped with camphorsulfonic acid was greatly changed in a range from 500 to 2000 nm, in which a new peak was observed in a range from about 500 to 1000 nm, and a Drude peak was significantly decreased in a range of 1000 nm or less. It can be noted that the spectrum was very similar to the known spectrum of polyaniline-emeraldine base. This indicates that a part of the polyaniline doped with camphorsulfonic acid was dedoped and converted into polyaniline-emeraldine base.

In addition, when the organic layer consisting of a polyaniline film doped with camphorsulfonic acid is doped with the titanium oxide B, an overall feature of a peak looked similar to an absorption spectrum of a polyaniline film doped with camphorsulfonic acid on a substrate.

Through the graph described above, it can be noted that polyaniline camphorsulfonate was changed into electrically-neutral polyaniline-emeraldine base by coating basic titanium oxide A. That is, it is concluded that the redox reaction was caused by coating the basic titanium oxide A, not the acidic titanium oxide B, and it leads to dedoping of polyaniline doped with camphorsulfonic acid having P-type conductivity, thereby being changed into electrically-neutral polyaniline-emeraldine base.

### Example 2

### Formation of Depletion Layer Using PEDOT:PSS (poly(3,4-ethylenedioxythiophene):poly(styrenesulfonate)) and Titanium Oxide Solution

In Example 2, PEDOT doped with PSS, instead of polyaniline of Example 1, was compared and analyzed with the titanium oxide A film of Example 1 and a multilayered thin film sequentially including PEDOT:PSS and a titanium oxide A, which is formed by reaction of these materials in optical characteristic.

A conductive polymer, a PEDOT:PSS solution, was dropped on a glass substrate, which was rotated at 3000 rpm for 1 minute and annealed on a hot plate at 120° C. for 1 hour to form a film.

After the film was completed, a transmittance was measured by a UV-Vis spectrometer, and then titanium oxide A solution was coated on top of the coated PEDOT:PSS film. In addition, for comparison, another film was formed by sequentially coating a glass substrate with titanium oxide A and PEDOT:PSS to have the same structure as the above-described film in an altered fabrication order, and then its transmittance spectrum was measured.

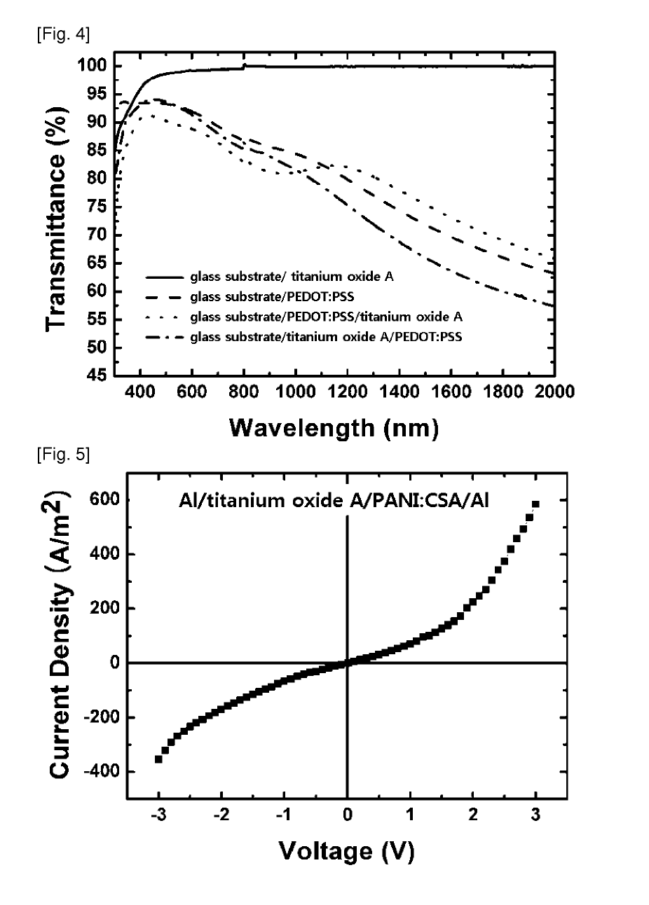

FIG. 4 is a graph of transmission spectrums for the films formed according to Example 2.

Referring to FIG. 4, PEDOT:PSS formed on a glass substrate shows a Drude peak exhibiting a metallic characteristic in a range from 500 to 2000 nm, which is similar to the polyaniline doped with camphorsulfonic acid of Example 1. However, titanium oxide A formed on a glass substrate exhibits a semiconductor characteristic in which almost no light is absorbed in a range from 500 to 2000 nm as in Example 1.

Meanwhile, a PEDOT:PSS film coated on the titanium oxide A shows a spectrum formed by simply combining transmittance spectra of the PEDOT:PSS and the titanium oxide A with each other. On the other hand, a thin layer in which titanium oxide A is coated on a PEDOT:PSS film shows a great change in a range from 500 to 2000 nm which is similar to when titanium oxide A is coated on polyaniline in Example 1. Particularly, a new peak is observed in a range from 800 to 1200 nm, and a Drude peak is significantly decreased in a range of 1000 nm or less. This indicates that a depletion layer is formed by partially dedoping PEDOT:PSS doped with a P-type dopant due to titanium oxide A.

That is, it can be noted that PEDOT:PSS having P-type conductivity is reduced at an interface with basic titanium oxide A, and thus is changed into an electrically-neutral depletion layer.

### Example 3

### Analysis of Multilayered Film of Polyaniline and Titanium Oxide in Electrical Characteristic

In Example 3, electrical characteristics of polyaniline and titanium oxides A and B were analyzed.

First, a glass substrate was cleaned and then an aluminum pattern was formed thereon. An organic layer consisting of polyaniline doped with camphorsulfonic acid and titanium oxide A were coated on the formed aluminum pattern. In addition, titanium oxide A was coated first on the aluminum pattern and gelated, and an organic layer consisting of polyaniline doped with camphorsulfonic acid was sequentially formed. Subsequently, aluminum was deposited in a vacuum on the two different membranes to form electrodes, respectively.

Final products were formed in a structure of a glass substrate, an aluminum electrode, a titanium oxide A layer, an organic layer and an aluminum electrode; and a structure of a glass substrate, an aluminum electrode, an organic layer, a titanium oxide A layer and an aluminum electrode.

FIG. 5 is a graph of voltage-current characteristics of the structure sequentially including the glass substrate, the aluminum electrode, the titanium oxide A, the organic layer and the aluminum electrode according to Example 3.

Referring to FIG. 5, the voltage-current graph generally exhibits linear characteristics, which indicates that there is no physical change between titanium oxide A and an organic layer, and a combination thereof is understood to have a simple structure having series connected resistors. This is because titanium oxide A is formed by coating a liquid-type titanium oxide solution and evaporating a solvent to gelate the solution, and a chemical reaction in a membrane to be formed later is prevented from occurring. As a result, it indicates that a redox reaction is inhibited between the previously formed and gelated titanium oxide A and polyaniline doped with camphorsulfonic acid having a P-type characteristic.

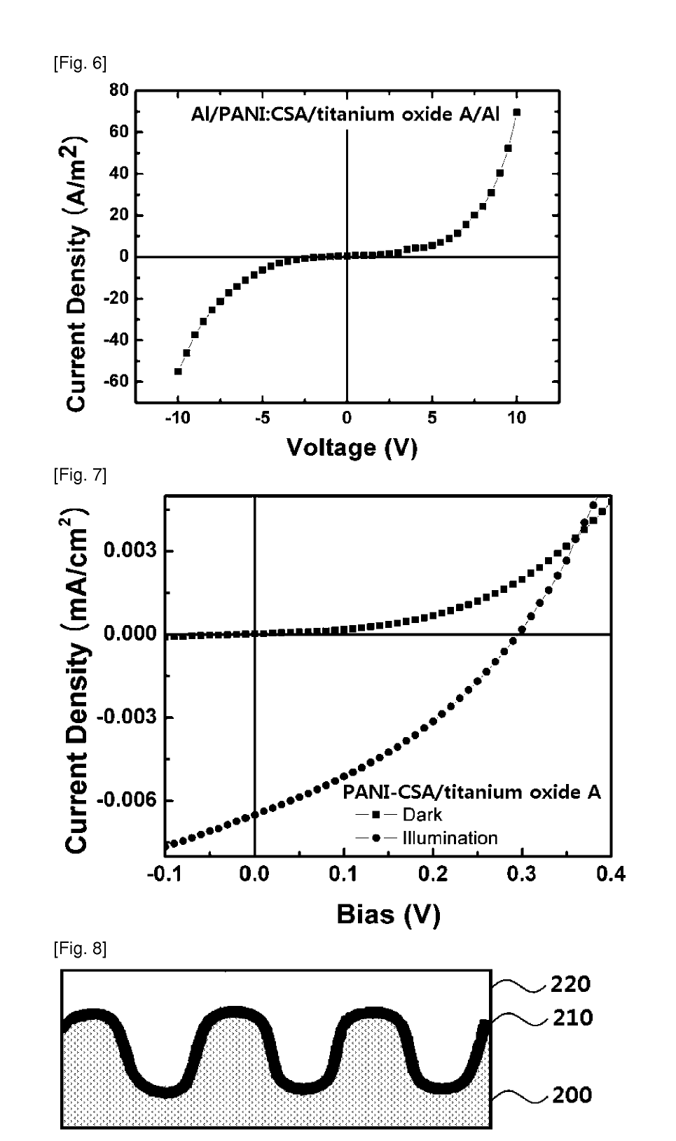

FIG. 6 is a graph of voltage-current characteristics of the structure sequentially including the glass substrate, the aluminum electrode, the organic layer, the titanium oxide A layer and the aluminum electrode according to Example 3.

Referring to FIG. 6, when more than 5 V of voltage is supplied, it is observed that current through a membrane is abruptly increased. This is a typical diode characteristic. That is, it indicates that an electrically-neutral depletion layer is present between two membranes respectively doped with P-type and N-type dopants, and a built-in potential generated according thereto shows in the structure of Example 3.

This is because an N-doped titanium oxide A solution is coated on a P-doped organic layer in a liquid phase, and thus gelation of the titanium oxide A solution occurs together with a redox reaction at an interface of the organic layer. That is, it means that the gelation of the basic titanium oxide A solution occurs together with the redox reaction at an interface of the organic layer, and thereby the P-doped organic layer is dedoped to be a neutral type.

### Example 4

### Fabrication of Photovoltaic Cell Using Polyaniline and Titanium Oxide

In Example 4, an organic photovoltaic cell was fabricated by junction of polyaniline and titanium oxide as shown in FIG. 2.

First, a glass substrate coated with indium tin oxide (ITO) was wiped off, and cleaned using an acetone solution in an ultrasonic cleaner for 1 hour. Afterward, the cleaning was sequentially repeated using neutral detergent, distilled water, acetone and alcohol each for 1 hour. The cleaned ITO substrate was put into a vacuum-dry oven at 100° C. for at least 1 hour to remove remaining alcohol from the substrate.

After the complete removal of alcohol, an ultraviolet ray was applied to a surface of the ITO surface for 1 hour to give it a hydrophilic property. When the preparation of the substrate was completed, a polyaniline solution doped with camphorsulfonic acid was dropped on the substrate, which was rotated at 1000 to 1500 rpm for 1 minute to form an organic layer, and placed on a hot plate at 80° C. for 10 minutes to remove a solvent.

Then, dilute titanium oxide solution was also coated on the substrate coated with polyaniline by rotating the substrate at 4000 rpm to dedope a polyaniline interface, and then the substrate coated sequentially with polyaniline and titanium oxide was annealed at 80° C. for 10 minutes and aluminum was vacuum deposited, as a negative electrode, and thus a device was completed. Here, in order to maximize the efficiency of the device, the fabrication process may be altered. For example, in order to control a thickness of a depletion layer, thicknesses of the doped polyaniline and the titanium oxide may be changed by variations of concentration of the solution or a rotation speed, and the annealing temperature or time with respect to the material may also be changed.

After the completion of the device, the device was put into an oxygen-free glove box, and irradiated with light having an intensity of 100 mW/cm2 on condition of AM 1.5G having a similar spectrum to the solar ray to analyze current-voltage characteristics.

FIG. 7 is a graph of voltage-current characteristics of an organic photovoltaic cell fabricated according to Example 4.

Referring to FIG. 7, current and voltage are not generated when no light is applied, and current is increased by application of bias. On the other hand, it can be noted that the application of light leads to production of short circuit current, which drives the photovoltaic cell.

### Example Embodiment 2

FIG. 8 is a cross-sectional view of an organic photovoltaic cell according to a second example embodiment of the present invention.

Referring to FIG. 8, a P-type organic layer 200 is formed on a substrate (not shown). Preferably, the P-type organic layer 200 consists of polyaniline doped with camphorsulfonic acid. The organic layer 200 is formed to have an uneven surface.

The uneven organic layer 200 may be formed in various methods. For example, the uneven organic layer 200 may be patterned by nano imprinting.

That is, polyaniline doped with camphorsulfonic acid is dissolved in a solvent such as meta-cresol, and the solution is doped by spin coating. Subsequently, a nano imprinting stamp patterned to have an uneven surface is introduced to the doped solution, and annealed on a hot plate to evaporate a solvent. Then, the stamp used for the nano imprinting is removed, and finally an uneven organic layer may be obtained.

For example, a polyaniline solution doped with camphorsulfonic acid dissolved in meta-cresol is dropped on the substrate having the ITO pattern, and a liquid-type organic film is formed while the organic solvent is not completely removed.

Afterward, the polyaniline film is pressed using a polydimethylsiloxane (PDMS) stamp patterned at several tens of nanometers to design an uneven pattern, annealed at a predetermined temperature to evaporate the solvent, and cooled to room temperature.

The PDMS stamp is removed from the cooled substrate, and thus a polyaniline pattern, the organic layer patterned to have an uneven surface may be obtained.

Alternatively, an uneven organic layer may be formed by depositing an organic material using a mask pattern having an uneven surface. The uneven organic layer 200 exhibits P-type conductivity.

Subsequently, an N-type metal oxide solution was coated on the organic layer 200. The metal oxide solution may be a titanium oxide solution. The titanium oxide solution exhibits basicity. The titanium oxide solution is the same as the titanium oxide disclosed in the first example embodiment.

Thus, a redox reaction occurs at an interface between the basic titanium oxide solution and the organic layer 200, and thereby a depletion layer 210 is formed along a surface of the uneven organic layer. The formation of the depletion layer 210 is caused by a dedoping phenomenon of the organic layer in response to the redox reaction at the interface between the organic layer and the titanium oxide solution. That is, due to the dedoping, the P-doped organic layer 200 is transformed into the electrically-neutral depletion layer 210.

In addition, the applied metal oxide solution is gelated, thereby forming a metal oxide layer 220. For example, when the metal oxide solution is a titanium oxide solution, the metal oxide layer 220 is formed of titanium oxide.

If the organic layer 200 is formed of polyaniline doped with camphorsulfonic acid, the organic layer 200 is partially converted into a neutral polyaniline-emeraldine base due to the redox reaction with the titanium oxide solution. That is, an electrically-neutral depletion region is formed along an uneven surface.

Accordingly, a photovoltaic cell having a great surface area may be fabricated, and charge migration occurring by absorption of light can be shortened as much as possible by using a depletion layer as a photoactive layer.

### INDUSTRIAL APPLICABILITY

One major advantage of an organic material is that it may be formed in various types, for example, metal to a insulator because it is capable of being easily doped or dedoped in response to a redox reaction. Such a redox reaction may occur in a super-small range in which electrons can be exchanged, and an intensity of the reaction is determined according to a doping degree and an acid-base strength. Thus, a doping region may be freely controlled by changing the intensity of the redox reaction. According to such a principle as described above, when an organic material is doped in a P type to form a film, and then a basic N-type material is coated on the film, the redox reaction occurs at an interface between two materials, and thus the interface is dedoped and reduced to a pre-doped state which does not have a free charge. This phenomenon makes fabrication of a novel-type semiconductor device possible since the dedoped surface serves as a depletion layer like that of an inorganic semiconductor. Also, since a thickness of the formed depletion layer is controlled by variations of pH concentration and a doping degree and the depletion layer can be formed by self-assembly, a novel-type nano semiconductor electronic device to which such a depletion layer is introduced may be formed in a super-small size through a very simple fabrication process. Further, in this process, in consideration of the characteristic that an organic material is difficult to be doped in an N type rather than in a P type, a novel organic-inorganic hybrid depletion layer having combined advantages of organic and inorganic materials may be fabricated through a similar P-N junction in response to the redox reaction using an N-doped inorganic material. Furthermore, an inorganic material formed by a sol-gel method can be applied to a wet process, and thus may maintain fabrication ease and flexibility which are advantages of the organic material. In addition, due to strong bonding between molecules, the inorganic material may overcome a disadvantage of an organic material, which is a short lifetime.

While the invention has been shown and described with reference to certain example embodiments thereof, it will be understood by those skilled in the art that various changes in form and details may be made therein without departing from the spirit and scope of the invention as defined by the appended claims.

1. An organic-inorganic hybrid junction device, comprising:
an organic layer doped with a P-type dopant;
a metal oxide layer doped with an N-type dopant, and formed by gelation of a basic metal oxide solution; and
a depletion layer interposed between the organic layer and the metal oxide layer, and formed by dedoping the organic layer at an interface between the organic layer and the metal oxide layer in response to an oxidation-reduction (redox) reaction of the organic layer and the metal oxide solution.

2. The device according to claim 1, wherein the organic layer includes a polymer selected from the group consisting of polyaniline-, polypyrrol-, polyacethylene-, poly(3,4-ethylenedioxythiophene (PEDOT)-, poly(phenylene-vinylene) (PPV)-, poly(fluorine)-, poly(para-phenylene) (PPP)-, poly(alkyl-thiophene)- and poly(pyridine) (PPy)-based materials, and combinations thereof.

3. The device according to claim 2, wherein the organic layer includes polyaniline doped with camphorsulfonic acid.

4. The device according to claim 3, wherein the depletion layer includes polyaniline-emeraldine base formed by dedoping of the organic layer in response to the redox reaction.

5. The device according to claim 1, wherein the metal oxide solution includes
a solvent evaporated in a concentration process;
metal alkoxide mixed in a volume percentage of 5 to 60% of an unconcentrated solvent;
an additive mixed in a volume percentage of 5 to 20% of the solvent; and
a dispersion solution for diluting gel-type metal oxide formed in the concentration process.

6. The device according to claim 5, wherein the metal alkoxide includes Ti, Zn, Sr, In, Ba, K, Nb, Fe, Ta, W, Sa, Bi, Ni, Cu, Mo, Ce, Pt, Ag, Rh, Ru or a combination thereof.

7. The device according to claim 5, wherein the solvent is alcohol, and the additive is alcohol amine, hydrogen peroxide or ammonium hydroxide.

8. The device according to claim 5, wherein the metal alkoxide is titanium isopropoxide, and the additive is ethanol amine.

9. The device according to claim 5, wherein the gel-type metal oxide includes the additive bonded to the metal alkoxide.

10. The device according to claim 5, wherein the dispersion includes alcohol, chloroform, chlorobenzene, dichlorobenzene, THF, xylene, DMF, DMSO or toluene.

11. The device according to claim 5, wherein the metal oxide solution is formed in the state where oxygen and moisture are removed.

12. An organic photovoltaic cell, comprising:
a first electrode formed on a substrate;
an organic layer formed on the first electrode and doped with a P-type dopant;
a metal oxide layer doped with an N-type dopant and formed by gelation of a basic metal oxide solution;
a depletion layer interposed between the organic layer and the metal oxide layer, formed by dedoping the organic layer at an interface between the organic layer and the metal oxide layer in response to a redox reaction of the organic layer and the metal oxide solution, and producing a free charge by light absorption; and
a second electrode formed on the metal oxide layer.

13. The cell according to claim 12, wherein the first electrode is formed of one selected from the group consisting of indium tin oxide (ITO), Al-doped zinc oxide (AZO), indium zinc oxide (IZO) and combinations thereof.

14. The cell according to claim 12, wherein the second electrode is formed of one selected from the group consisting of Al, Ba, Ca, In, Cu, Ag, Au, Yb, Sm and combinations thereof.

15. The cell according to claim 12, wherein the organic layer includes a polymer selected from the group consisting of polyaniline-, polypyrrol-, polyacethylene-, poly(3,4-ethylenedioxythiophene) (PEDOT)-, poly(phenylenevinylene) (PPV)-, poly(fluorine)-, poly(para-phenylene) (PPP)-, poly(alkyl-thiophene)- and poly(pyridine) (PPy)-based materials, and combinations thereof.

16. The cell according to claim 15, wherein the organic layer includes polyaniline doped with camphorsulfonic acid.

17. The cell according to claim 16, wherein the depletion layer includes polyaniline-emeraldine base formed by dedoping of the organic layer in response to the redox reaction.

18. The cell according to claim 12, wherein the metal oxide solution is a titanium oxide solution.

19. An organic photovoltaic cell, comprising:
an organic layer formed on a substrate and doped with a P-type dopant;
a depletion layer doped with an N-type dopant, formed along the uneven organic layer, and producing a free charge by light absorption; and
a metal oxide layer formed on the depletion layer,
wherein a junction interface between the organic layer, the depletion layer and the metal oxide layer is formed to have an uneven surface, the depletion layer is formed by dedoping the organic layer at an interface between the organic layer and the metal oxide layer in response to a redox reaction of the organic layer and the metal oxide solution, and the metal oxide layer is formed by gelation of the metal oxide solution.

20. The cell according to claim 19, wherein the organic layer includes polyaniline doped with camphorsulfonic acid, the depletion layer includes polyaniline-emeraldine base formed by dedoping the organic layer in response to the redox reaction, and the metal oxide solution is a titanium oxide solution.
